(19) United States
(12) Patent Application Publication
(10) Pub. No.: US 2013/0135890 A1
(43) Pub. Date: May 30, 2013

(54) EQUIPMENT INDICATOR LAMP AND METHOD FOR ASSEMBLING THE SAME

(71) Applicants: Lunzi Jing, Taoyuan Hsien (TW); Wuming Ku, Taoyuan Hsien (TW)

(72) Inventors: Lunzi Jing, Taoyuan Hsien (TW); Wuming Ku, Taoyuan Hsien (TW)

(73) Assignee: DELTA ELECTRONICS, INC., Taoyuan Hsien (TW)

(21) Appl. No.: 13/490,526

(22) Filed: Jun. 7, 2012

(30) Foreign Application Priority Data
Nov. 24, 2011 (CN) 201110379544.X

(51) Int. Cl. G02B 6/00; H05K 3/32; F21V 21/00

(52) U.S. Cl. 362/551; 362/382; 29/595

(57) ABSTRACT

The invention provides an equipment indicator lamp and a method for assembling the same. The equipment indicator lamp includes: a light source fixed and electrically connected to a circuit board; and a display part disposed on a housing of an equipment, so that the light emitted from the light source is projected out of the equipment via the display part. The equipment indicator lamp according to the invention has less elements, thus the material cost and manufacturing steps are reduced, the manufacturing process is easy to control, the lifespan of the light source is prolonged, and the whole appearance of the configuration become concise and artistic.

### CROSS REFERENCE TO RELATED APPLICATIONS

This application claims priority to the Chinese patent application No. 201110379544.X, filed Nov. 24, 2011, which is incorporated herein by reference in its entirety.

### TECHNICAL FIELD

The invention relates to an equipment indicator lamp and, more particularly, to an assembly configuration of the equipment indicator lamp, and a method for assembling the same.

### BACKGROUND ART

An equipment, such as a personal computer (PC), instrument and electronic device, usually has one or more indicator lamps (such as a power indicator lamp) for indicating the status of the equipment. In prior art, an equipment indicator lamp is provided with a configuration shown in FIG. 1.

In FIG. 1, the equipment indicator lamp includes a light source 1, the light source (such as a light emitting diode (LED) or a bulb) is mounted to a housing 2 of an equipment by a fixing means 12, and the light source 1 is electrically connected to a circuit board 3 through cables 8. Pins of the light source 1 are connected to the corresponding ends of the cables 8 at connecting points 11, respectively. Heat-shrinkable sleeves 10 are used to package and isolate the connecting points 11 to avoid electric shock or short circuit. Other ends of the cables 8 are connected to the circuit board 3 by respective terminals 9.

However, the configuration shown in FIG. 1, as well as its assembling process, has some drawbacks:

1. Numerous components to be assembled in the configuration, such as the lamp shown in FIG. 1 that essentially includes a light source 1, a fixing means 12, cables 8, terminals 9 and heat-shrinkable sleeves 10, increase the material cost.

2. Given the number of components, the assembly process can be varied and complicated. According to the above arrangement in the art, the assembly process of the indicator light essentially includes the steps of:
1) providing a light source 1;
2) mounting the light source 1 to a fixing means 12 and then mounting the fixing means 12 to a housing 2;
3) connecting pins of the light source 1 to corresponding ends of cables 8 respectively, in which operations such as welding and the like are needed, to achieve a stable electric connection;
4) installing and fixing other ends of the cables 8 to a circuit board 3 by terminals 9, in which some fixing manner such as welding, screwing and so forth is needed, to achieve the stable electric connection.

These steps are labor consuming.

3. In the course of fixing the light source 1 to the housing 2 by the fixing device 12 and connecting the light source 1 to the wires 8, the light source 1 may be damaged, which will affect the lifespan of the light source 1, and the process is hard to control.

4. Since the light source 1 is fixed to the housing 2, when an external force is applied to the housing 2, the light source 1 is easy to be damaged.

5. The whole appearance of the configuration is not artistic.

6. To meet the safety standard requirement, the cables 8 may need additional protective measures such as adding sleeves, cable ties and so on, which will cause additional material cost.

As a result, it is necessary to provide an equipment indicator lamp and a method for assembling the same to avoid the problems existed in prior art.

### SUMMARY OF THE INVENTION

One object of the present application, in part, is to overcome the drawbacks in prior art and provide an equipment indicator lamp and a method for assembling the same, such that the configuration of the equipment indicator lamp is simpler than that in prior art, and the equipment indicator lamp is convenient to assemble with labor-saving.

In one aspect, the invention provides an equipment indicator lamp, including: a light source, fixed and electrically connected to a circuit board inside an equipment; and a display part, disposed on a housing of the equipment and separated from the light source, wherein the light emitted from the light source is projected out of the equipment via the display part.

In some embodiments, the display part may comprise a light outlet hole penetrating the housing of the equipment, through which the light emitted from the light source is projected out of the equipment.

In some other embodiments, the display part may be provided with a light outlet means at the light outlet hole.

In further some embodiments, the light outlet means may be a light transmitting means made of transparent material, and the light transmitting device may block the light outlet hole.

In further some other embodiments, the light outlet means may be grille-shaped or net-shaped.

In still some embodiments, the equipment indicator lamp may further include a light guiding means for guiding the light emitted from the light source to the display part.

In still some other embodiments, the light guiding means may be made of optical fiber, one end of which is connected to the display part of the equipment, and the other end of which is connected to the light source by a connector.

In still some other embodiments, the light guiding means may be a reflecting element fixed inside the equipment, so that the light emitted from the light source may be reflected to the display part via the reflecting element.

In still some other embodiments, the equipment indicator lamp may further include a fixing bracket, which is fixed to the circuit board and holds the light source with a certain angle, so that the light emitted from the light source can be projected to the display part directly.

In another aspect, the application also discloses a method for assembling an equipment indicator lamp, including steps of: providing a light source; fixing and electrically connecting the light source to a circuit board inside an equipment; and disposing a display part separated from the light source onto a housing of the equipment, so that the light emitted from the light source can be projected out of the equipment via the display part.

According to some aspects of the invention, the invention breaks through the conventional method for assembling the equipment indicator lamp. By means of fixing the light source directly to the circuit board rather than the housing of the equipment, and directly projecting or indirectly leading the light emitted from the light source out of the equipment, the components of the equipment can be simplified, and the amount of the elements to be assembled can be reduced. Besides, the material cost and manufacturing steps both can be reduced, the manufacturing process can be easy to control, the lifespan of the light source can be prolonged, and the whole appearance of the configuration may become concise and artistic.

Hereinafter, the above objects, characteristics and beneficial advantages of the present invention will be described in detail with reference to the accompanying drawings.

### BRIEF DESCRIPTION OF THE DRAWINGS

The accompanying drawings, which are included to provide further understanding of the disclosure and are incorporated in and constitute a part of this application, illustrate embodiments of the disclosure and together with the description serve to explain the principle of the disclosure. In the drawings,

FIG. 1 is a schematic view of a conventional equipment indicator lamp;

FIG. 2 is a schematic view of an exemplary equipment indicator lamp according to some aspects;

FIG. 3 is a schematic view of an exemplary equipment indicator lamp according to some aspects; and

FIG. 4 is a schematic view of an exemplary equipment indicator lamp according to some aspects.

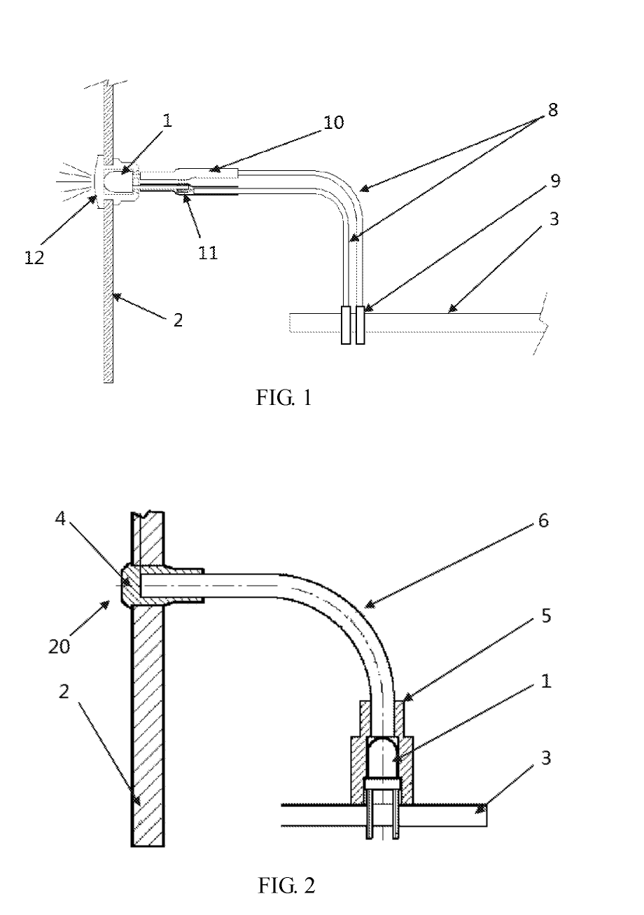

### DETAILED DESCRIPTION OF THE PREFERRED EMBODIMENTS

Description of the present application will now be given in detail, with reference to the accompanying drawings.

FIG. 2 is a schematic view of an equipment indicator lamp according to some aspects of this application. As shown in FIG. 2, the equipment indicator lamp includes: a light source 1 directly fixed and electrically connected to a circuit board 3; a display part 20 mounted on a housing 2 of an equipment and separated from the light source 1, wherein the light emitted from the light source 1 is guided to the display part 20 of the equipment by a light guiding means 6 and projected out of the equipment via the display part 20.

In some embodiments, the light source 1 may be a LED, a bulb or other illumination devices. In addition, the equipment indicator lamp shown in FIG. 2 may be used as a power indicator of a PC to achieve the long-distance display, which, however, is merely illustrative, and the equipment indicator lamp is not limited to the particular embodiments described herein. The equipment indicator lamp may, in general, be provided in any suitable equipment (or electronic device) and also used to display for other various functions.

In some embodiments, the display part 20 may include a light outlet hole penetrating the housing 2 of the equipment, through which the light guided by the light guiding means 6 is projected out of the equipment. Preferably, the display part 20 may also include a light outlet means 4 disposed at the light outlet hole. The light outlet means 4 can be any light transmitting means made of transparent materials with various colors, and can be designed to block the light outlet hole. Further, the light outlet means 4 can also be grill-shaped or net-shaped. It should be noticed that the light outlet means can also be made of non-transparent material when it is grill-shaped or net-shaped. Thus, on the one hand, the light guided by the light guiding means 6 can be projected out of the equipment with desired color or luminance through the light outlet means 4; on the other hand, the light outlet means 4 can make the display part 20 of the equipment more artistic. Besides, if the light outlet means 4 is a light transmitting means blocking the light outlet hole, foreign matters can be prevented from entering the equipment.

In FIG. 2, the light guiding means 6 may be made of optical fiber, one end of which is connected to the display part 20, and the other end of which is connected to the light source 1 by a connector 5. It should be understood that, when the display part 20 only includes a light outlet hole, one end of the optical fiber can be directly inserted into and fixed in the light outlet hole; when the display part 20 further includes a light outlet means 4, the one end of the optical fiber may be provided in various ways according to the disposing mode of the light outlet means 4. For example, one end of the optical fiber may be inserted into and fixed in the light outlet means 4 when the light outlet means 4 itself is inserted through the light outlet hole. It should be stated that a skilled person in the art can determine the method for fixing the light guiding means 6 according to the different designs of the display part 20, and the invention is not limited to the particular embodiments described.

As illustrated above, compared with the prior art, the equipment indicator lamp of the invention, in part, has some notable advantages below:

1. The amount of elements to be assembled of the equipment indicator lamp is reduced, and as described above, the equipment indicator lamp only includes one light source 1, one display part 20 and one light guiding means 6 for guiding the light emitted from the light source 1 to the display part 20. The amount of components to be assembled is reduced, so is the material cost.

2. Because of the reduced components, the steps of the assembly process are greatly reduced too. That is, the following steps are sufficient to complete the assembling of the equipment indicator lamp:
1) providing a light source 1;
2) fixing and electrically connecting the light source 1 to a circuit board 3 inside an equipment;
3) disposing a display part 20 separated from the light source 1 onto a housing of the equipment such that the light emitted from the light source 1 may be projected out of the equipment via the display part 20. Specially, a light guiding means 6 can be used in such a way that one end of the light guiding means 6 is connected to the display part 20 of the equipment and the other end thereof is connected to the light source 1, thus the light can be guided out of the equipment.

Therefore, the above assembly process of the invention is more labor-saving, more convenient and simpler than before.

3. The technology process of fixing and electrically connecting the light source 1 to the circuit board 3 is commonly-used and mature, so the process is easy to control. Besides, since the light source 1 is fixed on the circuit board 3 inside the equipment, the light source 1 is not easily affected when the housing 2 of the equipment is subjected to external force, so that the possibility of the light source 1 being damaged is minimized, and the lifespan of the light source 1 is prolonged.

4. The whole appearance of the configuration is concise and artistic.

5. Since wires are omitted, the configuration in the invention is safer and more reliable.

Hereinafter, variants of the equipment indicator lamp would be further illustrated.

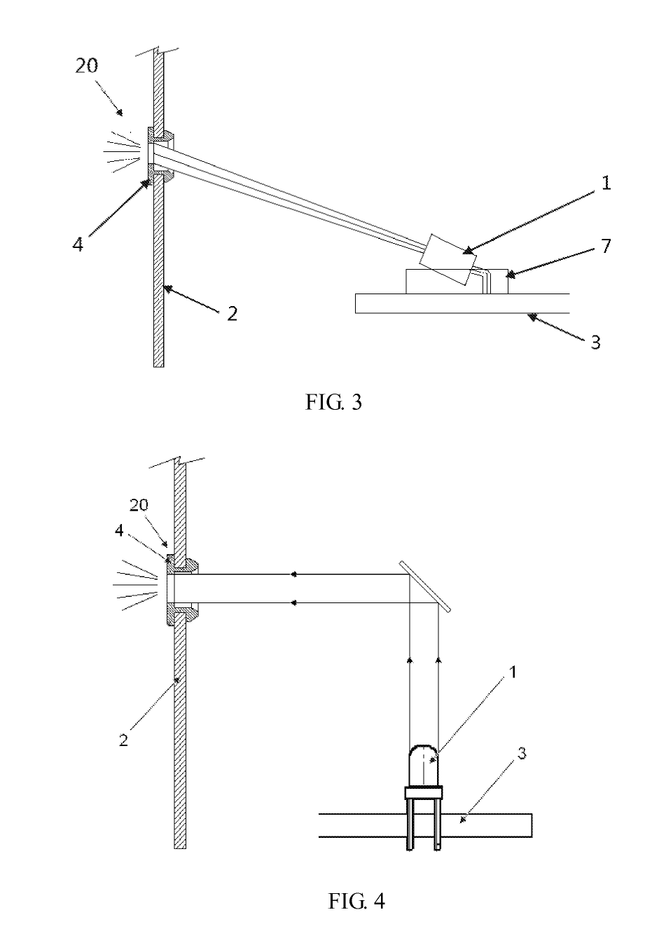

FIG. 3 is a schematic view of the equipment indicator lamp according to some other embodiments of the invention. As shown in FIG. 3, the equipment indicator lamp includes: a light source 1 fixed and electrically connected to a circuit board 3; a display part 20 disposed on a housing 2 of an equipment and separated from the light source 1, via which the light emitted from the light source 1 is projected out of the equipment; and a fixing bracket 7 fixed to a circuit board 3, wherein the light source 1 is held on the circuit board 3 by the fixing bracket 7 with a certain angle (for example, the light source 1 is inclined), so that the light emitted from the light source 1 can be projected to the display part 20 of the equipment directly. In the second embodiment, the arrangement of the light source 1 and the display part 20 can be the same as that in the first embodiment, so the description to them is omitted here.

Compared to FIG. 2, the equipment indicator lamp of FIG. 3 omits the light guiding means 6 and has the light source 1 fixed to the circuit board 3 with a certain angle, so that the light emitted from the light source 1 can be directly projected to the display part 20.

Accordingly, the equipment indicator lamp may only include a light source 1, a display part 20 and a fixing bracket 7. As a result, the equipment indicator lamp thus illustrated has all the advantages previously provided, and further reduces material and labor cost.

Alternatively, a reflecting element may be disposed on the light path and fixed inside the equipment, so that the light emitted from the light source 1 can be reflected to the display part 20 by the reflecting element.

As schematically shown in FIG. 4, the equipment indicator lamp may only include a light source 1, a display part 20 and a reflecting element, wherein the light source 1 is designed to be directly disposed in a circuit board 3, so that both the connector 5 of FIG. 2 and the fixing bracket 7 of FIG. 3 can be omitted.

When the light is blocked by other components on the linear light path from the light source 1 to the display part 20, the reflecting element can be used to reflect the light to change the light path, so that the light from the light source 1 can be projected to a desired position such as the display part 20. It should be stated that, the number of the reflecting elements is not limited to that shown in FIG. 4, and can be selected and designed according to the practical situation.

The foregoing embodiments and advantages are merely exemplary and are not to be construed as limiting the present disclosure. This description is intended to be illustrative, and not to limit the scope of the claims. Many alternatives, modifications and variations will be apparent to those skilled in the art. The features, structures, methods and other characteristics of the exemplary embodiments described herein may be combined in various ways to obtain additional and/or alternative exemplary embodiments.

As the present features may be embodied in many forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are intended to be embraced by the appended claims.

What is claimed is:

1. An equipment indicator lamp comprising:
a light source fixed and electrically connected to a circuit board within an equipment; and
a display part mounted on a housing of the equipment and separated from the light source, wherein the light emitted from the light source is projected out of the equipment via the display part.

2. The equipment indicator lamp according to claim 1, wherein the display part comprises a light outlet hole penetrating through the housing, and the light emitted from the light source is projected out of the equipment through the light outlet hole.

3. The equipment indicator lamp according to claim 2, wherein the display part is provided with a light outlet means at the light outlet hole.

4. The equipment indicator lamp according to claim 3, wherein the light outlet means is a light transmitting means made of transparent material, and the light outlet hole is filled with the light transmitting device.

5. The equipment indicator lamp according to claim 3, wherein the light outlet means is grille-shaped or net-shaped.

6. The equipment indicator lamp according to claim 1, further comprising a light guiding means for guiding the light emitted from the light source to the display part.

7. The equipment indicator lamp according to claim 6, wherein the light guiding means comprises optical fiber that connects between the display part, and the light source by a connector.

8. The equipment indicator lamp according to claim 6, wherein the light guiding means is a reflecting element fixed inside the equipment, by which the light emitted from the light source is reflected to the display part.

9. The equipment indicator lamp according to claim 1, further comprising a fixing bracket, which is fixed to the circuit board and holds the light source with a certain angle, so that the light emitted from the light source is projected to the display part directly.

10. A method for assembling an equipment indicator lamp according to claim 1, comprising:
providing a light source;
fixing and electrically connecting the light source to a circuit board within an equipment; and
disposing a display part separated from the light source onto a housing of the equipment, so that the light emitted from the light source is projected out of the equipment via the display part.
